(19) United States
(12) Patent Application Publication
(10) Pub. No.: US 2005/0098904 A1
(43) Pub. Date: May 12, 2005

(54) Transparent small memory card

(76) Inventor: Pierre Liu, Hsinchu Hsien (TW)

Correspondence Address: Keith Kline;PRO-TECHTOR INTERNATIONAL, 20775 Norada Court, Saratoga, CA, 95070-3018, US

(21) Appl. No.: 10/705,384

(22) Filed: Nov. 10, 2003

(51) Int. Cl. H01L 23/28

(52) U.S. Cl. 257/787

(57) ABSTRACT

A transparent small memory card includes a substrate, at least one memory chip and a transparent glue layer, the substrate is formed with an upper surface and a lower surface, the upper surface is formed with a plurality of connected points and a plurality of golden fingers electrically connected to the plurality of connected points, the substrate is used to arrange in the electric device, so that the plurality of golden fingers of the substrate may be electrically connected to the electric device, the memory chip, which is arranged on the upper surface of the substrate, electrically connected to the plurality of connected points of the upper surface, the transparent glue layer encapsulated the memory chip and display the mark of the memory chip or the substrate. Thus, the mark of the small memory card or the substrate may displayed via the transparent glue layer, so that there's no need to stamp specially any mark on the memory card, and the manufacturing processes may be convenient.

### BACKGROUND OF THE INVENTION

1. Field of the Invention

The present invention relates to a transparent small memory card, and more particular to a small memory card with special style.

2. Description of the Related Art

Referring to FIG. 1 showing the side schematic illustrates of a prior memory card, the golden finger 15 is used to insert into a slot of a computer main-board, there are active elements and passive elements on the module card, the active elements usually are packed into an integrated circuit 11. Each integrated circuit 11 encapsulated a chip 12, which may be a memory chip, for example a flash memory chip. The pins 13 of integrated circuit 11 are mounted on the printed circuit board 14 of the memory card by SMT, the printed circuit board 14 has solder points 17 connected to pins 13.

The conventional memory card is packaged by the opaque glue layer, first step was to encapsulate the chip 12 into integrated circuit 11, then mount the integrated circuit 11 on the printed circuit board 14 by SMT, but the manufacturing process is inconvenient, either the surface unable display the special style and reveal the mark of the chip 12, so we must especially stamp the mark on the glue layer, absolutely add the manufacturing cost. A chip 12 must be packed then mounted on the circuit board 14, so more steps is unnecessary leads to the manufacturing cost will be increased. As to a memory card always includes many ICs so that the integrated circuit 11 must be mounted on the PCB 14 one by one during manufacturing the module card. Moreover, the cost of SMT is expensive, special the manufacture devices such as a SMT machine and a solder furnace will extra the cost of equipment.

### SUMMARY OF THE INVENTION

The object of the present invention is to provide a transparent small memory card may be manufactured conveniently, the manufacturing processes may be simplified and the manufacturing cost may decrease.

Another object of the present invention is to provide a transparent small memory card with the revealed mark of the chip to rid of the manufacturing process of stamp mark on the glue layer.

To achieve the above-mentioned object, the present invention includes a substrate, at least one memory chip and a transparent glue layer. The substrate has an upper surface and a lower surface, the upper surface is formed with a plurality of connected points and a plurality of golden fingers electrically connected to the plurality of connected points, the substrate is arranged on the upper surface of the substrate, so that the plurality of the golden fingers of the upper surface may be electrically connected an electrical device, the memory chip, which is arranged on the upper surface of the substrate, electrically connected the plurality of connected points of the upper surface, the transparent glue layer is encapsulated the memory chip to protect the memory chip and reveal the mark on the memory chip or the substrate.

According to one aspect of the present invention, the heat of the memory chip may be traveled via the disperse heat slice. Therefore, proving the durability and dependability of small memory card.

### BRIEF DESCRIPTION OF THE DRAWINGS

FIG. 1 is a schematic illustrates showing a conventional small memory card structure.

FIG. 2 is the first cross-sectional view illustrates showing a transparent small memory card of the present invention.

FIG. 3 is the second cross-sectional view illustrates showing a transparent small memory card structure of the present invention.

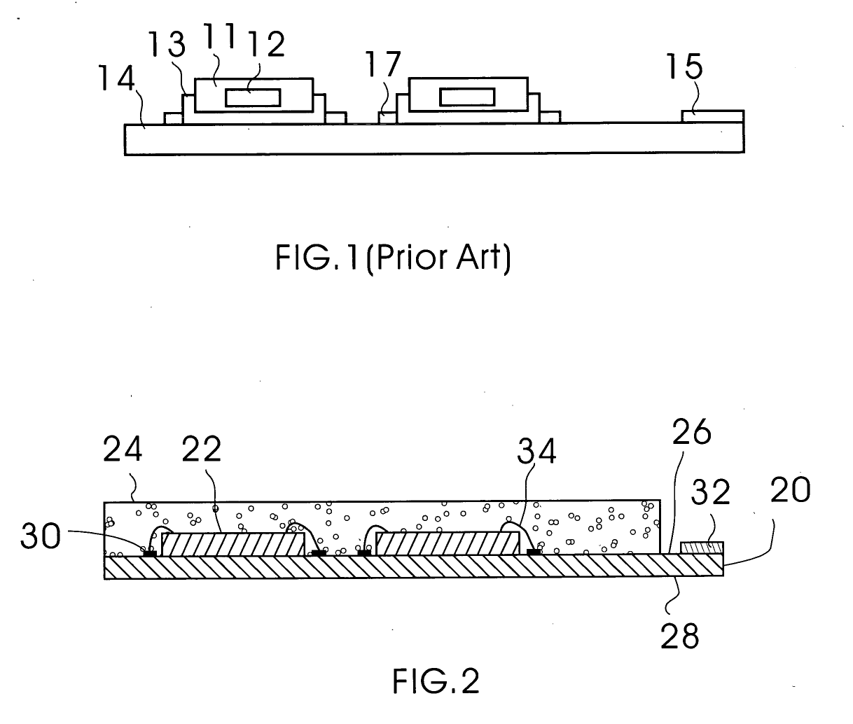

### DETAILED DESCRIPTION OF THE INVENTION

FIG. 2 is showing the cross-section view illustrates showing a transparent small memory card of the present invention, which included a substrate 20, two upper memory chips 22 and a transparent glue layer 24.

The substrate 20 is formed with an upper surface 26 and a lower surface 28, the upper surface 26 is formed with a plurality of connected points 30 and a plurality of golden fingers 32 are electrically connected to a plurality of connected points 30, the substrate 20 is to be set in an electric device, so that the plurality of golden fingers 32 may be electrically connected to the electric device.

Two memory chips 22, which are arranged on the upper surface 26 of the substrate 20, electrically connected to a plurality of connected points 34 of the upper surface 26 of the substrate 20 via a plurality of wires 34.

A transparent glue layer 24 is encapsulated two memory chips 22 to protect the memory chips 22 and display the mark on the memory chip 22 or the substrate 20.

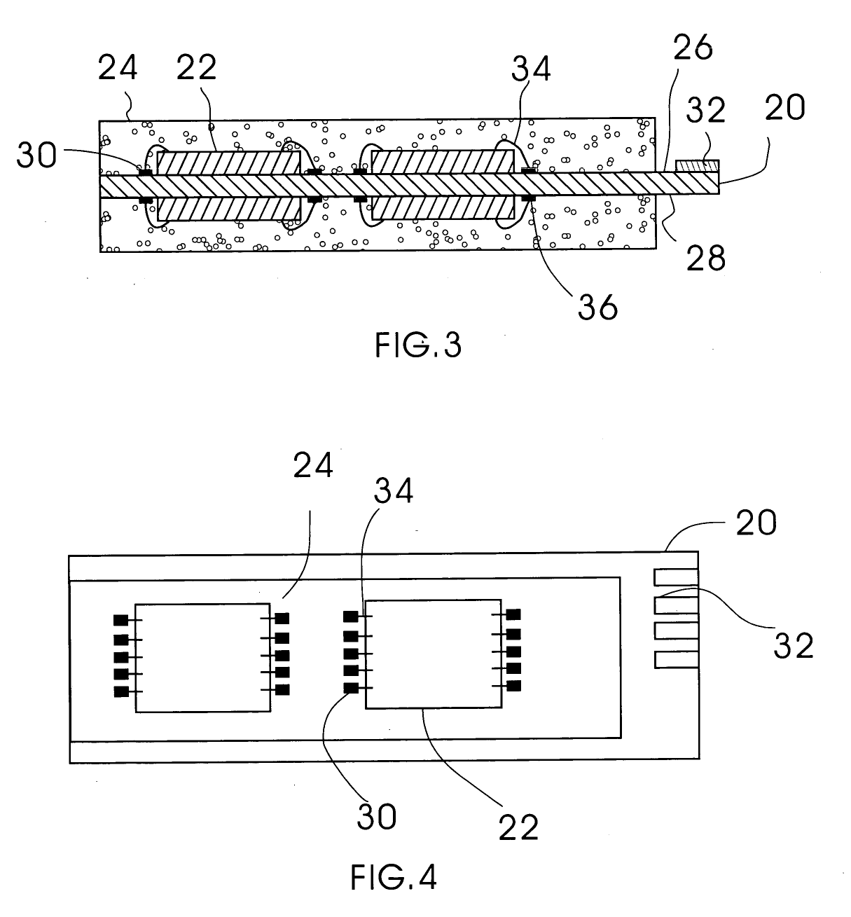

Referring to FIG. 3 is the second cross-sectional view illustrates showing a transparent small memory card structure of the present invention, in the embodiment include four memory chips 22, the lower surface 28 of the substrate 20 is formed with connected points 36, wherein two memory chips 22 are mounted on the upper surface 26 of the substrate 20, and further the two memory chips 22 are electrically connected to the connected points 36 of lower surface 28 of the substrate 20 by wires 34.

The transparent glue layer 24 is encapsulated the upper surface 26 and lower surface 28 of the substrate, so that the four memory chips 22 may be protected.

Referring to FIG. 4, the mark of the four memory chips 22 or the substrate 20 may be revealed, so there is no need to stamp another mark on the memory card, the manufacturing processes may be simplified and the manufacturing cost may be decrease.

Therefore, the small memory card of the present invention has the following advantages.

1. Since the upper memory chip 22 is mounted on the substrate 20, and then the memory chip 22 is encapsulated in glue layer 24, so the manufacturing processes may be simplified and the manufacturing cost may decrease.

2. Since the mark of the memory chip 22 or the substrate 20 may be displayed through transparent glue layer 24, so the memory or the substrate may be recognized easily, the manufacturing process may be also decreased.

3. While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A transparent small memory card to be set in an electric device, comprising:
A substrate having an upper surface and a lower surface, the upper surface formed with a plurality of connected points and a plurality of golden fingers electrically connected to the plurality of connected points, the substrate is used to set in the electric device, so that the golden fingers on the upper surface of the substrate may be electrically connected to the electric device;
At least one memory chip, which arranged on the upper surface of the substrate, electrically connected to a plurality of connected points on the upper surface; and
A transparent glue layer encapsulated the memory chip is used to protect the memory chip and display the mark of the memory chip or the substrate.

2. The transparent small memory card according to claim 1, wherein the lower surface of the substrate arranged a memory chip, and the transparent glue layer is encapsulated the memory chip.

3. The transparent small memory card according to claim 1, wherein the upper surface of the substrate is arranged two memory chips, and the transparent glue layer is encapsulated the two memory chips at the same time.

4. The transparent small memory card according to claim 1, wherein the memory chip is electrically connected to the connected points of the upper surface of the substrate by wires.
